(19) United States
(12) Patent Application Publication
(10) Pub. No.: US 2013/0277810 A1
(43) Pub. Date: Oct. 24, 2013

(54) METHOD FOR FORMING HEAT SINK WITH THROUGH SILICON VIAS

(71) Applicants: Juan Boon Tan, Singapore (SG); Yeow Kheng Lim, Singapore (SG); Shao Ning Yuan, Singapore (SG); Soh Yun Siah, Singapore (SG)

(72) Inventors: Juan Boon Tan, Singapore (SG); Yeow Kheng Lim, Singapore (SG); Shao Ning Yuan, Singapore (SG); Soh Yun Siah, Singapore (SG)

(73) Assignee: GLOBALFOUNDRIES Singapore Pte. Ltd., Singapore (SG)

(21) Appl. No.: 13/453,762

(22) Filed: Apr. 23, 2012

(51) Int. Cl. H01L 29/02; H01L 21/768

(52) U.S. Cl. 257/629; 438/584; 257/E21.586; 257/E29.002

(57) ABSTRACT

Semiconductor devices are formed with through silicon vias extending into the semiconductor substrate from a backside surface for improved heat dissipation. Embodiments include forming a cavity in a backside surface of a substrate, the substrate including a gate stack on a frontside surface, and filling the cavity with a thermally conductive material.

### TECHNICAL FIELD

The present disclosure relates to a method of fabricating semiconductor devices with backside cooling. The present disclosure is particularly applicable to semiconductor devices in 65 nanometer (nm) technology nodes and beyond.

### BACKGROUND

The integration of hundreds of millions of circuit elements, such as transistors, on a single integrated circuit necessitates further scaling down or micro-miniaturization of the physical dimensions of circuit elements, including interconnection structures. Micro-miniaturization has engendered a dramatic increase in transistor engineering complexity, resulting in several problems.

One such problem is the difficulty in dissipating heat generated by the integrated circuit. This difficulty is compounded based on the micro-miniaturization of the physical dimensions of circuit elements such that more heat is produced in smaller areas. This heat may build-up in the substrates of the integrated circuits causing, for example, degradation of the substrate.

A need therefore exists for methodology enabling fabrication of semiconductor devices with improved cooling efficiency and the resulting structure.

### SUMMARY

An aspect of the present disclosure is an efficient method of fabricating a semiconductor device with through silicon vias extending into the semiconductor substrate from a backside surface.

Another aspect of the present disclosure is a semiconductor device including through silicon vias extending into the semiconductor substrate from a backside surface.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a cavity in a backside surface of a substrate, the substrate including a gate stack on a frontside surface; and filling the cavity with a thermally conductive material.

Aspects of the present disclosure include forming a liner material layer in the cavity prior to filling the cavity with the thermally conductive material. Another aspect includes filling the cavity by electrochemical plating (ECP). A further aspect includes forming a second cavity in the backside surface of the substrate, and filling the second cavity with the thermally conductive material, where a pitch ratio of an average diameter of the first and second cavities to a distance between the first and second cavities is 1:x, where x can be 2 or larger. An additional aspect includes forming the cavity to a depth of 6 to 10 μm. Yet an additional aspect includes forming the cavity to a width of 6 μm or larger at the backside surface of the substrate. Yet an additional aspect includes aligning the cavity with an area of higher heat generation. Another aspect includes forming a layer of the thermally conductive material on the backside surface of the substrate.

Another aspect of the present disclosure includes a method including: etching a backside surface of a silicon substrate forming cavities in the backside surface, the substrate including at least one gate stack on a frontside surface; forming a liner in each cavity; forming a metal barrier layer over the liner; and electrochemical plating copper on the backside surface of the substrate, filling the cavities with copper, forming through silicon vias (TSVs) in the backside surface of the substrate.

Another aspect of the present disclosure is a device including: a substrate having a frontside surface and a backside surface, the substrate including a gate stack on the frontside surface; and a thermally conductive material extending into the substrate from the backside surface.

Aspects include a device including copper as the thermally conductive material. Further aspects include a layer of liner material between the thermally conductive material and the substrate, for example, having a thickness of 0.3 to 0.8 μm. An additional aspect includes a metal barrier layer over the layer of liner material. Yet another aspect includes the thermally conductive material comprising a pair of TSVs, and a pitch ratio of an average diameter of the TSVs and a distance between the pair of TSVs is 1:x, where x can be 2 or larger. Another aspect includes the TSVs having a width at the backside surface of the substrate of 6 μm or larger. A further aspect includes the thermally conductive material being aligned with an area of higher heat generation. An additional aspect includes the thermally conductive material extending 6 to 10 μm into the substrate. Further aspects include a layer of the thermally conductive material on the backside surface of the substrate, for example, having a thickness of 3 to 6 μm.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 to 6 schematically illustrate a process flow for fabricating a semiconductor device having through silicon vias extending into the semiconductor substrate from a backside surface of the substrate, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of the buildup of heat in semiconductor devices. In accordance with embodiments of the present disclosure, TSVs are formed extending into a substrate of a semiconductor device from a backside surface of the substrate to increase the cooling efficiency of the semiconductor device.

Methodology in accordance with embodiments of the present disclosure includes forming a cavity in a backside surface of a substrate, such as by etching the substrate. The substrate may include a gate stack on a frontside surface of the substrate or may be subsequently processed to include a gate stack on the frontside surface. Next, a liner material layer is formed in the cavity, and a metal barrier layer may be formed over the liner material layer. Subsequently, the cavity is filled with a thermally conductive material forming a through silicon via. The through silicon via may be formed in an area that is expected to experience heat in the operation of the gate stack.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

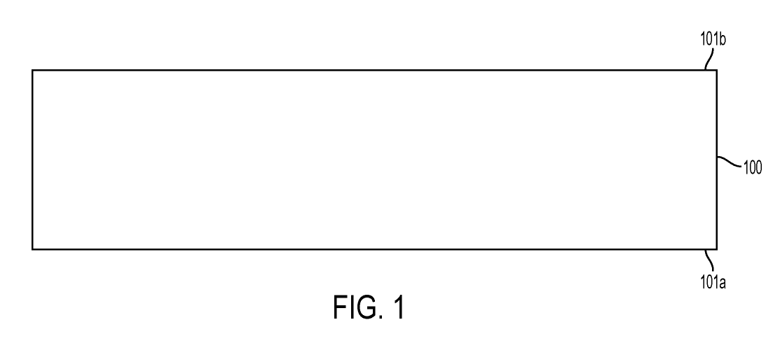

Adverting to FIG. 1, a method for forming backside TSVs, in accordance with an exemplary embodiment, begins with a semiconductor substrate 100 that includes a backside surface 101a and a frontside surface 101b. As illustrated in FIG. 1, the semiconductor substrate 100 may not yet have been processed to include, for example, a gate stack on the frontside surface 101b. However, in one embodiment, the semiconductor substrate 100 may include a gate stack and/or any other logic device (not shown for illustrative convenience) on the frontside surface 101b at the beginning of forming backside TSVs. The semiconductor substrate 100 may be any semiconductor substrate material, such as silicon.

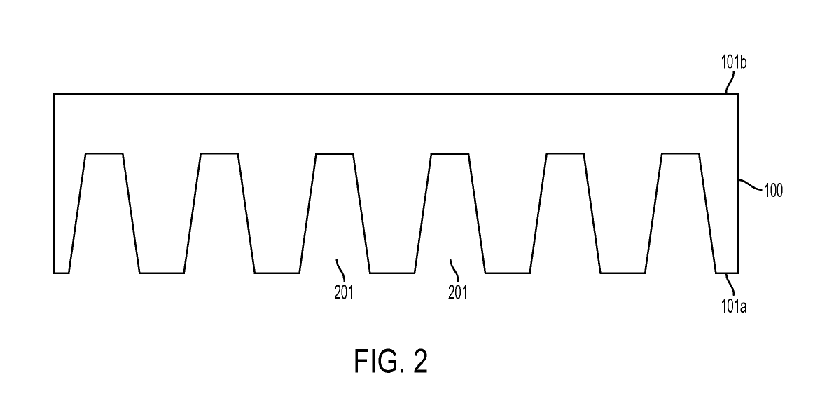

Next, cavities 201 are formed extending into the substrate 100 from the backside surface 101a, as illustrated in FIG. 2. The cavities 201 may be formed according to any conventional process, such as conventional TSV mask and etch. The cavities 201 may be of any size and aspect ratio. For example, the diameter of the cavities may be 6 μm or larger, and the pitch ratio of the cavities 201 may be 1:x, where x can be 2 or larger. Accordingly, for cavities 201 that are 8 μm in diameter, the cavities 201 are spaced 40 μm apart. The depth of the cavities 201 into the substrate 100 may be 6 to 10 μm. The cavities 201 may also be formed to leave a distance of 1.5 to 2 μm between the ends of the cavities 201 and the frontside surface 101b of the substrate 100 such that the cavities 201 do not affect the gate stack and/or logic devices on the frontside surface 101b.

The cavities 201 may be formed without being aligned with any gate stack and/or logic device that may be on the frontside surface 101b of the substrate 100. Alternatively, the cavities 201 may be formed to be in alignment with any gate stack and/or logic device that may be on the frontside surface 101b of the substrate 100. As a further alternative, although the cavities 201 may not be in alignment with any gate stack and/or logic device on the frontside surface 101b of the substrate 100, the placement of the cavities 201 may be concentrated at an area where heat generation from the gate stacks and/or logic devices on the frontside surface 101b is the highest.

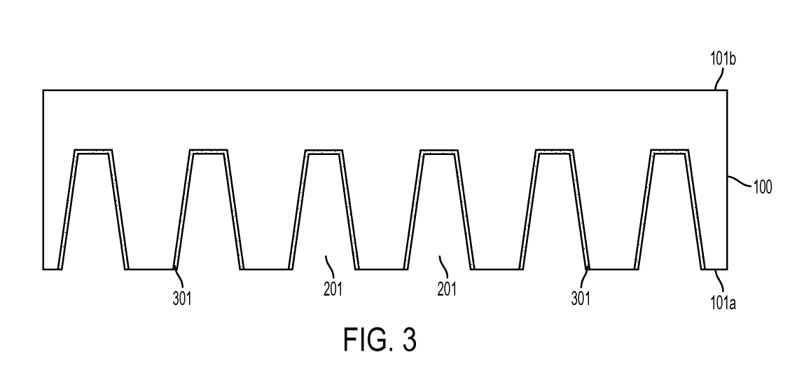

As illustrated in FIG. 3, the cavities 201 are then lined with an oxide liner layer 301. The oxide liner layer 301 may be formed to a thickness of 0.3 to 0.8 μm. Exemplary materials of the oxide liner layer are thermal or CVD silicon dioxide (SiO₂), silicon oxynitride (SiON), or tetraethyl orthosilicate (TEOS). The oxide liner layer provides an isolation layer. The oxide liner layer 301 may be formed by any conventional process.

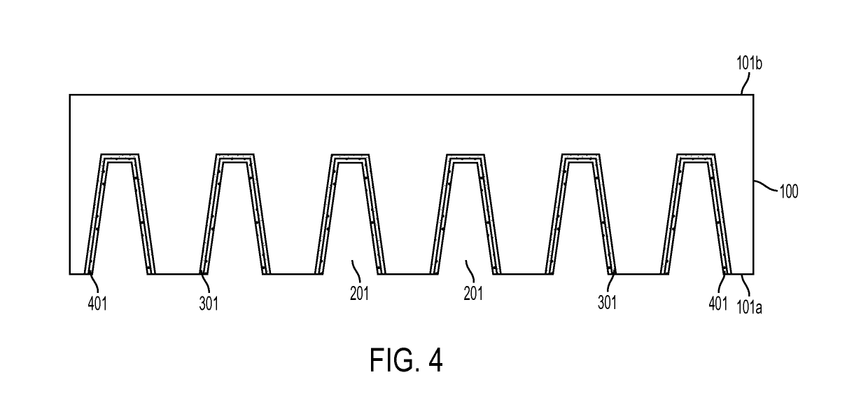

Adverting to FIG. 4, the cavities 201 are then lined with a metal barrier layer 401 over the oxide liner layer 301. The metal barrier layer 401 may be formed to a thickness of 8 to 12 nm. The metal barrier layer 401 may be made of tantalum (Ta), tantalum nitride (TaN), titanium (Ti), or titanium nitride (TiN), or a combination thereof.

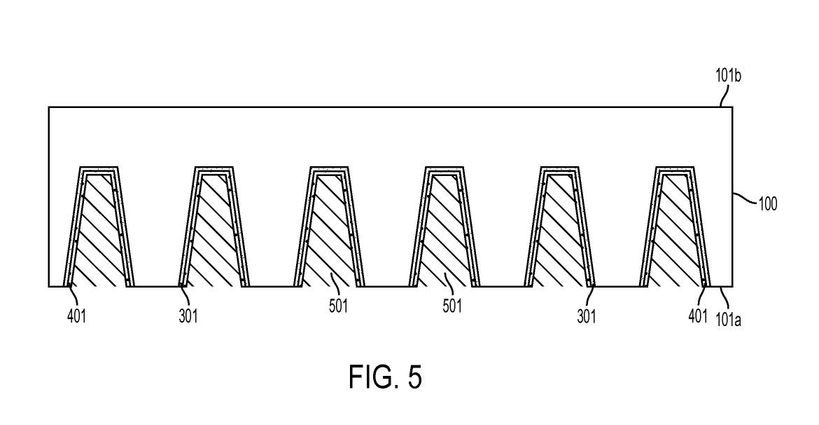

Subsequently, the cavities 201 are filled with a thermally conductive material 501, as illustrated in FIG. 5. The thermally conductive material 501 may be comprised of any thermally conductive material, such as copper (Cu), aluminum (Al), or tungsten (W), or an alloy or combination thereof. The thermally conductive material 501 may be deposited by any conventional process, such as by electrochemical plating (ECP) when the material is copper. Thus, upon depositing the thermally conductive material 501, TSVs are formed extending into the backside surface 101a of the substrate 100 that allow for the transport of heat away from the gate stacks and/or logic devices on the frontside surface 101b of the substrate 100.

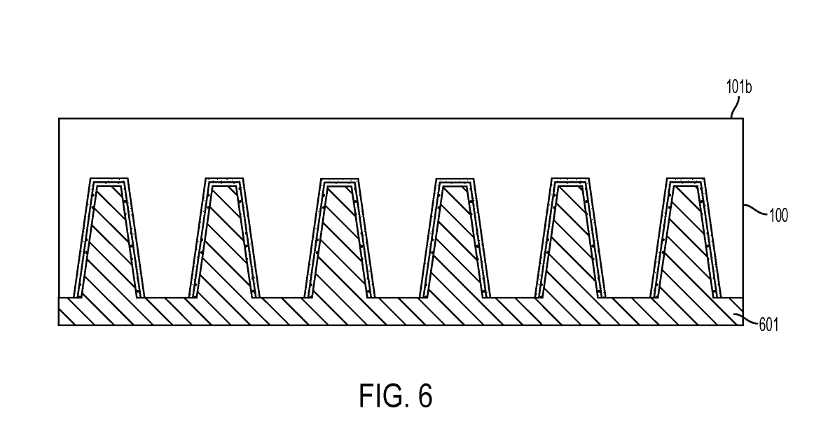

As illustrated in FIG. 6, the thermally conductive material 501 may additionally be deposited to form a layer 601 of thermally conductive material 501 on the backside surface 101a of the substrate 100. The layer 601 may be formed to a thickness of 3 to 6 μm. The surface of the layer 601 may be treated to passivate the thermally conductive material 501 of the layer 601 and prevent corrosion. By way of example, for copper, the layer 601 may be treated to form cupric oxide (CuO) and/or cuprous oxide (Cu₂O), or copper silicide (Cu₅Si). Alternatively, any copper on the backside substrate surface 101a, for example layer 601, may be polished away, and a single copper damascene process may be employed to form a copper pattern (not shown for illustrative convenience) on top of the thermally conductive material 501 and routed to a heat sink to further improve the cooling efficiency.

The embodiments of the present disclosure achieve several technical effects, including improved cooling efficiency of semiconductor devices. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a cavity in a backside surface of a substrate, the substrate including a gate stack on a frontside surface; and
filling the cavity with a thermally conductive material.

2. The method according to claim 1, further comprising filling the cavity by electrochemical plating (ECP).

3. The method according to claim 1, further comprising forming a liner material layer in the cavity prior to filling the cavity with the thermally conductive material.

4. The method according to claim 1, further comprising:
forming a second cavity in the backside surface of the substrate; and
filling the second cavity with the thermally conductive material,
wherein a pitch ratio of an average diameter of the first and second cavities to a distance between the first and second cavities is 1:x, where x is 2 or larger.

5. The method according to claim 1, further comprising forming the cavity to a depth of 6 to 10 μm into the substrate.

6. The method according to claim 1, further comprising forming the cavity to a width of 6 μm or larger at the backside surface of the substrate.

7. The method according to claim 1, further comprising aligning the cavity with an area of higher heat generation.

8. The method according to claim 1, further comprising forming a layer of the thermally conductive material on the backside surface of the substrate.

9. A device comprising:
a substrate having a frontside surface and a backside surface, the substrate including a gate stack on the frontside surface; and
a thermally conductive material extending into the substrate from the backside surface.

10. The device according to claim 9, wherein the thermally conductive material comprises copper.

11. The device according to claim 10, further comprising a layer of liner material between the thermally conductive material and the substrate.

12. The device according to claim 11, further comprising a metal barrier layer over the layer of liner material.

13. The device according to claim 11, wherein the layer of liner material has a thickness of 0.3 to 0.8 μm.

14. The device according to claim 9, wherein the thermally conductive material comprises a pair of through silicon vias (TSVs), and a pitch ratio of an average diameter of the TSVs to a distance between the pair of TSVs is 1:x, where x is 2 or larger.

15. The device according to claim 14, wherein the TSVs have a width of 6 μm or larger at the backside surface of the substrate.

16. The device according to claim 9, wherein the thermally conductive material is aligned with an area of higher heat generation.

17. The device according to claim 9, wherein the thermally conductive material extends 6 to 10 μm into the substrate.

18. The device according to claim 9, further comprising a layer of the thermally conductive material on the backside surface of the substrate.

19. The device according to claim 18, wherein the layer of the thermally conductive material has a thickness of 3 to 6 μm.

20. A method comprising:
etching a backside surface of a silicon substrate forming cavities in the backside surface, the substrate including at least one gate stack on a frontside surface;
forming a liner in each cavity;
forming a metal barrier layer over each liner; and
electrochemical plating copper on the backside surface of the substrate, filling the cavities with copper, forming through silicon vias (TSVs) in the backside surface of the substrate.
